(19) United States
(12) Patent Application Publication
(10) Pub. No.: US 2020/0087779 A1
(43) Pub. Date: Mar. 19, 2020

(54) SUBSTRATE SUPPORTING DEVICE FOR VACUUM SPUTTERING EQUIPMENT

(71) Applicant: Shenzhen China Star Optoelectronics Technology Co., Ltd., Shenzhen, Guangdong (CN)

(72) Inventor: Qiuping HUANG, Shenzhen, Guangdong (CN)

(21) Appl. No.: 15/747,627

(22) PCT Filed: Jan. 4, 2018
(86) PCT No.: PCT/CN2018/071258

§ 371 Date: Jan. 25, 2018

(30) Foreign Application Priority Data
Dec. 27, 2017 (CN) 201711449740.3

(51) Int. Cl. C23C 14/50; C23C 14/34

(52) U.S. Cl. CPC C23C 14/50; C23C 14/34

(57) ABSTRACT

A substrate supporting device for a vacuum sputtering equipment is provided, including a frame and a plurality of first bars and second bars intercrossing each other and arranged on the frame. A plurality of nodes is formed at intersections of the first and the second bars, and a plurality of pins configured to support the substrate is mounted on at least a part of the nodes. In the disclosure, by mounting the bars formed in a mesh shape on the frame, the entire range of the substrate can be stabilized, and the vibration and the fragment may be reduced; the first and the second bars have a smaller width so as to reduce the isolation effect on the temperature, and the mesh holes formed between the first and the second bars are uniformly distributed in the frame to avoid the uneven film quality caused by the difference in heating temperature.

### RELATED APPLICATIONS

The present application is a National Phase of International Application Number PCT/CN2018/071258, filed Jan. 4, 2018, and claims the priority of China Application No. 201711449740.3, filed Dec. 27, 2017.

### FIELD OF THE DISCLOSURE

The disclosure relates to the field of screen display technology, and in particular to a substrate supporting device for a vacuum sputtering equipment.

### BACKGROUND

Vacuum sputtering equipment used in the flat panel display (FPD) industry needs to be provided with a supporting device for placing a substrate on a supporting device and performing transmission in order to carry out sputtering film formation on the substrate.

In order to support and stabilize the substrate, reduce vibration and fragmentation of the substrate in transmission, as shown in FIG. 1, a plurality of bars 2′ is usually deposited on a frame 1′ of the supporting device, a plurality of pins 3′ are mounted on the bars 2′ and the frame 1′, configured to stabilize and support the substrate during transmission, and reduce vibration of the substrate, thereby avoiding fragmentation and scratches.

Due to the presence of bars and pins, the heating temperature difference between the region A having bars and the region B having no bars will be caused, thereby producing the nonuniformity of the film quality and resulting in Mura phenomenon.

### SUMMARY

The technical problem to be solved in the disclosure is to provide a substrate supporting device applied to a vacuum sputtering equipment, so as to reduce heat insulation and reduce nonuniformity of the film forming quality.

To solve the technical problem, the disclosure provides a substrate supporting device applied to a vacuum sputtering equipment, including:

a frame, and

a plurality of first bars and second bars intercrossing each other and arranged on the frame, wherein a plurality of nodes is formed at intersections of the first bars and the second bars, and a plurality of pins configured to support the substrate are fixedly mounted on at least a part of the nodes.

The frame is rectangular, and the pins are symmetrically distributed with a center of the frame.

A plurality of mesh holes is formed between the first bars and the second bars intercrossing each other, and the mesh holes are uniformly distributed in the frame.

The first bars are parallel to and spaced from each other in a transverse direction, and the second bars are parallel to and spaced apart from each other in a longitudinal direction.

Both the first bars and the second bars are obliquely crossed.

A cross section of the first bars or the second bars is circular, and a diameter of the circle is from 5 mm to 30 mm.

A cross section of the first bars or the second bars is rectangular, and a long side of the rectangle is from 5 mm to 30 mm.

A cross section of the first bars or the second bars is square, and a side length of the square is from 5 mm to 30 mm.

The first bars and the second bars are metal bars, and the pins are an insulating material.

The frame is fixedly mounted with a least one pin, a height of the pins is equal to that of the pins fixedly mounted on the nodes.

The beneficial effects of the embodiments of the disclosure are as follows: by mounting the bars formed in the shape of a mesh on the frame, the entire range of the upper, lower, left, and right sides of the substrate can be stabilized, the substrate may have more stable support and vibration suppression, and the vibration and the fragment may be reduced; the first bars and the second bars have a smaller width so as to reduce the isolation effect on the temperature, and the mesh holes formed between the first bars and the second bars intercrossing each other are uniformly distributed in the frame to avoid the occurrence of uneven film quality caused by the difference in heating temperature.

### BRIEF DESCRIPTION OF THE DRAWINGS

In order to illustrate technical schemes of the disclosure or the prior art more clearly, the following section briefly introduces drawings used to describe the embodiments and prior art. Obviously, the drawing in the following descriptions is just some embodiments of the disclosure. The ordinary person in the related art can acquire the other drawings according to these drawings without offering creative effort.

FIG. 1 is a schematic structural diagram of a conventional substrate supporting device.

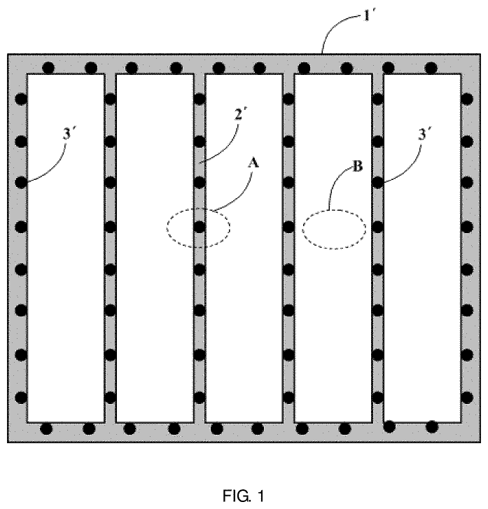

FIG. 2 is a schematic structural diagram of a substrate supporting device for a vacuum sputtering equipment according to an embodiment of the disclosure.

FIG. 3 is a schematic side view of a substrate supporting device for a vacuum sputtering equipment according to an embodiment of the disclosure.

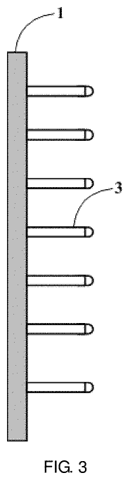

### DETAILED DESCRIPTION OF PREFERRED EMBODIMENTS

The following description of various embodiments is made with reference to the accompanying drawings to illustrate specific embodiments in which the disclosure may be practiced.

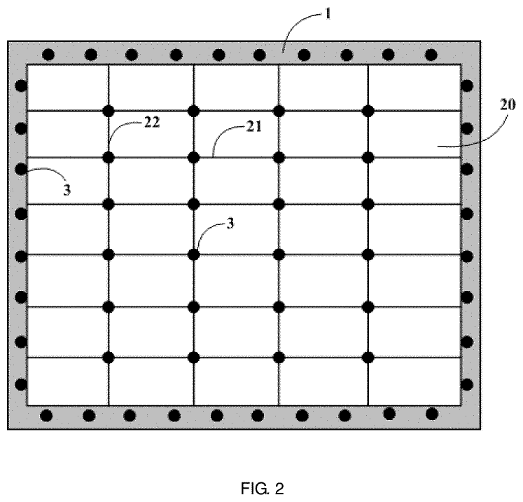

Referring to FIG. 2, an embodiment of the disclosure provides a substrate supporting device for a vacuum sputtering equipment, including:

a frame 1, and

a plurality of first bars 21 and second bars 22 intercrossing each other and arranged on the frame 1, and a plurality of nodes are formed at intersections of the first bars 21 and the second bars 22, and a plurality of pins 3 configured to support the substrate are fixedly mounted on at least a part of the nodes.

Specifically, the frame 1 has a rectangular shape. The first bars 21 and the second bars 22 may be mounted on the frame 1 in any manner by welding, riveting, bolting, etc., preferably by bolts, for easy disassembly. at least one pins 3 is mounted on the frame 1, and a height of the pins is equal to that of the pins 3 fixedly mounted on the nodes, so as to ensure the stable support to the substrate.

Each of the nodes formed by the first bars 21 and the second bars 22 can be fixedly mounted with a plurality of pins 3. If the pins 3 are fixedly mounted on a part of the nodes, in order to maintain the uniform support to the substrate, the pins 3 are symmetrically distributed with the center of the frame 1. According to the vibration of the substrate, the number and location of the supporting pins can also be adjusted accordingly.

A plurality of mesh holes 20 are formed between the first bars 21 and the second bars 22 intercrossing each other. The mesh holes 20 are evenly distributed in the frame 1, so as to avoid uneven film quality caused by the difference in heating temperature. Simultaneously, according to the vibration of the substrate, the density of the mesh holes 20 in the frame 1 can be reduced when the data of the simulation and the actual test reach the minimum specification value, that is, the interval between the first bars 21 and the second bars 22 are correspondingly adjusted, so as to increase the area of the mesh holes 20 and reduce the number of the mesh holes 20.

The first bars 21 are parallel to and spaced apart from each other in the transverse direction, and the second bars 22 are parallel to and spaced apart from each other in the longitudinal direction, thereby forming a support mesh having the bars intercrossing in the longitudinal direction and the transverse direction. Because the frame 1 is rectangular, the first bars 21 are vertically connected to the left and right sides of the frame 1, and the second bars 2 are vertically connected to the upper and lower sides of the frame 1. Since there are more bars in the horizontal and vertical directions than those in the prior art, the effect of suppressing the vibration of the substrate can be effectively improved. As another example, the first bars 21 and the second bars 22 may also be disposed obliquely to each other, that is, non-perpendicularly connected to the frame 1 respectively. The first bars 21 and the second bars 22 forming a mesh shape have a solid effect on the entire upper, lower, left, and right sides of the substrate and have more stable support and vibration suppression, and can greatly reduce vibration and fragmentation.

The first bars 21 and the second bars 22 of the embodiment have a smaller width and can greatly reduce the thermal insulation. Specifically, in some embodiments, a cross section of the first bars 21 or the second bars 22 is a circle, and a diameter of the circle is from 5 mm to 30 mm; in some embodiments, the cross section of the first bars 21 or the second bars 2 is a rectangle, and a long side of the rectangle is from 5 mm to 30 mm; in other embodiments, the cross section of the first bars 21 or the second bars 22 is square, and a side length of the square is from 5 mm to 30 mm.

The first bars 21 and the second bars 22 are made of metal to ensure the rigidity of the support; and the pins 3 are made of insulating material, so as to avoid electrical conduction with the substrate when the pins 3 support the substrate.

The substrate supporting device of the embodiment of the disclosure is an upright supporting platform when working, commonly known as a tray, used in a large vacuum sputtering equipment; the tray is divided into an inner tray and an outer tray, both sandwiching the substrate, thereby the substrate can be transferred in a vacuum chamber. In the substrate supporting device of the embodiment of the disclosure, a mesh formed by the bars is added to the inner tray, and the pins are fixedly mounted on the nodes of the bars, applied to the manufacturing process of the substrate.

It can be seen from the above description that the beneficial effects of the embodiments of the disclosure are as follows: by mounting the bars formed in the shape of a mesh on the frame, the entire range of the upper, lower, left, and right sides of the substrate can be stabilized, the substrate may have more stable support and vibration suppression, and the vibration and the fragment may be reduced; the first bars and the second bars have a smaller width so as to reduce the isolation effect on the temperature, and the mesh holes formed between the first bars and the second bars intercrossing each other are uniformly distributed in the frame to avoid the occurrence of uneven film quality caused by the difference in heating temperature.

The above disclosure is only the preferred embodiments of the disclosure, and certainly cannot be used to limit the scope of the disclosure. Therefore, equivalent changes made according to the claims of the disclosure are still within the scope of the disclosure.

What is claimed is:

1. A substrate supporting device for a vacuum sputtering equipment, comprising:
a frame; and
a plurality of first bars and second bars intercrossing each other and arranged on the frame, wherein a plurality of nodes is formed at intersections of the first bars and the second bars, and a plurality of pins configured to support a substrate are fixedly mounted on at least a part of the nodes.

2. The substrate supporting device according to claim 1, wherein the frame is rectangular, and the pins are symmetrically distributed with a center of the frame.

3. The substrate supporting device according to claim 1, wherein a plurality of mesh holes is formed between the first bars and the second bars intercrossing each other, and the mesh holes are uniformly distributed in the frame.

4. The substrate supporting device according to claim 1, wherein the first bars are parallel to and spaced from each other in a transverse direction, and the second bars are parallel to and spaced from each other in a longitudinal direction.

5. The substrate supporting device according to claim 1, wherein the first bars and the second bars are obliquely crossed.

6. The substrate supporting device according to claim 1, wherein a cross section of the first bars or the second bars is a circle, and the diameter of the circle is from 5 mm to 30 mm.

7. The substrate supporting device according to claim 1, wherein a cross section of the first bars or the second bars is a rectangle, and a long side of the rectangle is from 5 mm to 30 mm.

8. The substrate supporting device according to claim 1, wherein a cross section of the first bars or the second bars is a square, and a side length of the square is from 5 mm to 30 mm.

9. The substrate supporting device according to claim 1, wherein the first bars and the second bars are metal bars, and the pins are an insulating material.

10. The substrate supporting device according to claim 1, wherein the frame is fixedly mounted with a plurality of pins, a height of the pins is equal to that of the pins fixedly mounted on the nodes.
